(19) United States
(12) Patent Application Publication
(10) Pub. No.: US 2023/0413570 A1
(43) Pub. Date: Dec. 21, 2023

(54) THREE-DIMENSIONAL MEMORY DEVICE AND METHOD FOR FORMING THE SAME

(71) Applicant: YANGTZE MEMORY TECHNOLOGIES CO., LTD., Wuhan (CN)

(72) Inventors: Kun Zhang, Wuhan (CN); Wenxi Zhou, Wuhan (CN); Zhiliang Xia, Wuhan (CN); Di Wang, Wuhan (CN); Wei Liu, Wuhan (CN); Zongliang Huo, Wuhan (CN)

(21) Appl. No.: 17/845,443

(22) Filed: Jun. 21, 2022

(51) Int. Cl. H01L 27/11575; H01L 27/11582

(52) U.S. Cl. CPC H01L 27/11575; H01L 27/11582

(57) ABSTRACT

A three-dimensional (3D) memory device includes a plurality of memory planes and a separation block. Each memory plane includes a plurality of memory blocks. Each memory block includes a memory stack including interleaved conductive layers and first dielectric layers, and a plurality of channel structures each extending through the memory stack. The separation block extending laterally to separate each two adjacent memory planes. Each separation block includes a dielectric stack including interleaved second dielectric layers and the first dielectric layers. The first dielectric layers extend across the memory blocks and the separation block, and the second dielectric layers separate the conductive layers of two adjacent memory blocks.

### BACKGROUND

The present disclosure relates to memory devices and methods for forming memory devices.

Planar semiconductor devices, such as memory cells, are scaled to smaller sizes by improving process technology, circuit design, programming algorithm, and fabrication process. However, as feature sizes of the semiconductor devices approach a lower limit, planar process and fabrication techniques become challenging and costly. A three-dimensional (3D) semiconductor device architecture can address the density limitation in some planar semiconductor devices, for example, Flash memory devices.

### SUMMARY

In one aspect, a 3D memory device is disclosed. The 3D memory device includes a plurality of memory planes and a separation block. Each memory plane includes a plurality of memory blocks. Each memory block includes a memory stack including interleaved conductive layers and first dielectric layers, and a plurality of channel structures each extending through the memory stack. The separation block extending laterally to separate each two adjacent memory planes. Each separation block includes a dielectric stack including interleaved second dielectric layers and the first dielectric layers. The first dielectric layers extend across the memory blocks and the separation block, and the second dielectric layers separate the conductive layers of two adjacent memory blocks.

In some implementations, each separation block further includes a plurality of dummy channel structures extending in the dielectric stack. In some implementations, the dummy channel structures extend through partial of the dielectric stack.

In some implementations, a diameter of the channel structures is larger than a diameter of the dummy channel structures. In some implementations, each memory block further includes at least one slit structure extending through the memory stack. In some implementations, at least one channel structure is disposed between the slit structure and the separation block.

In another aspect, a 3D memory device is disclosed. The 3D memory device includes a plurality of memory planes and a separation block. Each memory plane includes a plurality of memory blocks. Each memory block includes a memory stack including interleaved conductive layers and first dielectric layers, a plurality of channel structures each extending through the memory stack, and a slit structure extending through the memory stack. The separation block extends laterally to separate each two adjacent memory planes. Each separation block includes a dielectric stack including interleaved second dielectric layers and the first dielectric layers.

In some implementations, the slit structure is disposed only in the plurality of memory blocks. In some implementations, the first dielectric layers extend across the memory blocks and the separation block, and the second dielectric layers separate the conductive layers in two adjacent memory blocks.

In some implementations, the separation block further includes a plurality of dummy channel structures each extending in the dielectric stack. In some implementations, the dummy channel structures extend through partial of the dielectric stack.

In some implementations, a diameter of the channel structures is larger than a diameter of the dummy channel structures. In some implementations, at least one channel structure is disposed between the slit structure and the separation block. In some implementations, at least one channel structure is disposed between the slit structure and the dummy channel structures.

In still another aspect, a system is disclosed. The system includes a 3D memory device configured to store data, and a memory controller. The 3D memory device includes a plurality of memory planes and a separation block. Each memory plane includes a plurality of memory blocks. Each memory block includes a memory stack including interleaved conductive layers and first dielectric layers, and a plurality of channel structures each extending through the memory stack. The separation block extending laterally to separate each two adjacent memory planes. Each separation block includes a dielectric stack including interleaved second dielectric layers and the first dielectric layers. The first dielectric layers extend across the memory blocks and the separation block, and the second dielectric layers separate the conductive layers of two adjacent memory blocks. The memory controller is coupled to the 3D memory device and is configured to control operations of the 3D memory device.

In yet another aspect, a system is disclosed. The system includes a 3D memory device configured to store data, and a memory controller. The 3D memory device includes a plurality of memory planes and a separation block. Each memory plane includes a plurality of memory blocks. Each memory block includes a memory stack including interleaved conductive layers and first dielectric layers, a plurality of channel structures each extending through the memory stack, and a slit structure extending through the memory stack. The separation block extends laterally to separate each two adjacent memory planes. Each separation block includes a dielectric stack including interleaved second dielectric layers and the first dielectric layers. The memory controller is coupled to the 3D memory device and is configured to control operations of the 3D memory device.

In yet another aspect, a method for forming a 3D memory device is disclosed. A stack structure having a plurality of first dielectric layers and a plurality of second dielectric layers alternatingly arranged is formed on a substrate. A plurality of channel structures extending vertically through the stack structure are formed in a plurality of memory planes. A plurality of openings extending vertically through the stack structure are formed in the plurality of memory planes. A first portion of the plurality of second dielectric layers in the plurality of memory planes is removed to form a plurality of cavities, and a second portion of the plurality of second dielectric layers in a separation block between adjacent memory planes is maintained. A plurality of word lines are formed in the plurality of cavities. A plurality of slit structures are formed in the plurality of openings.

In some implementations, the first portion of the plurality of second dielectric layers in the plurality of memory planes is removed through the plurality of openings.

In some implementations, a plurality of channel openings are formed extending through the stack structure in the plurality of memory planes, and the plurality of channel structures are formed in the plurality of channel openings.

In some implementations, a plurality of dummy channel openings are formed extending through the stack structure in the separation block between adjacent memory planes, and a plurality of dummy channel structures are formed in the plurality of dummy channel openings.

In some implementations, a first length of the plurality of channel structures is larger than a second length of the plurality of dummy channel structures.

In some implementations, a size of the plurality of channel structures is larger than a size of the plurality of dummy channel structures.

### BRIEF DESCRIPTION OF THE DRAWINGS

The accompanying drawings, which are incorporated herein and form a part of the specification, illustrate aspects of the present disclosure and, together with the description, further serve to explain the present disclosure and to enable a person skilled in the pertinent art to make and use the present disclosure.

FIGS. 1A-1C illustrate plan views of an exemplary 3D memory device, according to some aspects of the present disclosure.

FIG. 1D illustrates a cross-sections of an exemplary 3D memory device, according to some aspects of the present disclosure.

FIGS. 2-4 illustrate cross-sections of an exemplary 3D memory device, according to some aspects of the present disclosure.

FIG. 5 illustrates a plan view of an exemplary 3D memory device, according to some aspects of the present disclosure.

FIGS. 6-11 illustrate cross-sections of an exemplary 3D memory device at different stages of a manufacturing process, according to some aspects of the present disclosure.

FIG. 12 illustrates a flowchart of an exemplary method for forming a 3D memory device, according to some aspects of the present disclosure.

FIG. 13 illustrates a block diagram of an exemplary system having a memory device, according to some aspects of the present disclosure.

FIG. 14A illustrates a diagram of an exemplary memory card having a memory device, according to some aspects of the present disclosure.

FIG. 14B illustrates a diagram of an exemplary solid-state drive (SSD) having a memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductor and contact layers (in which interconnect lines and/or via contacts are formed) and one or more dielectric layers.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “3D memory device” refers to a semiconductor device with vertically oriented strings of memory cell transistors (referred to herein as “memory strings,” such as NAND memory strings) on a laterally-oriented substrate so that the memory strings extend in the vertical direction with respect to the substrate. As used herein, the term “vertical/vertically” means nominally perpendicular to the lateral surface of a substrate.

A 3D semiconductor device can be formed by stacking semiconductor wafers or dies and interconnecting them vertically so that the resulting structure acts as a single device to achieve performance improvements at reduced power and a smaller footprint than conventional planar processes. As the shrinkage of the device size and thickness, how to increase the storage capacity per unit area is one of the bottlenecks of the 3D memory devices.

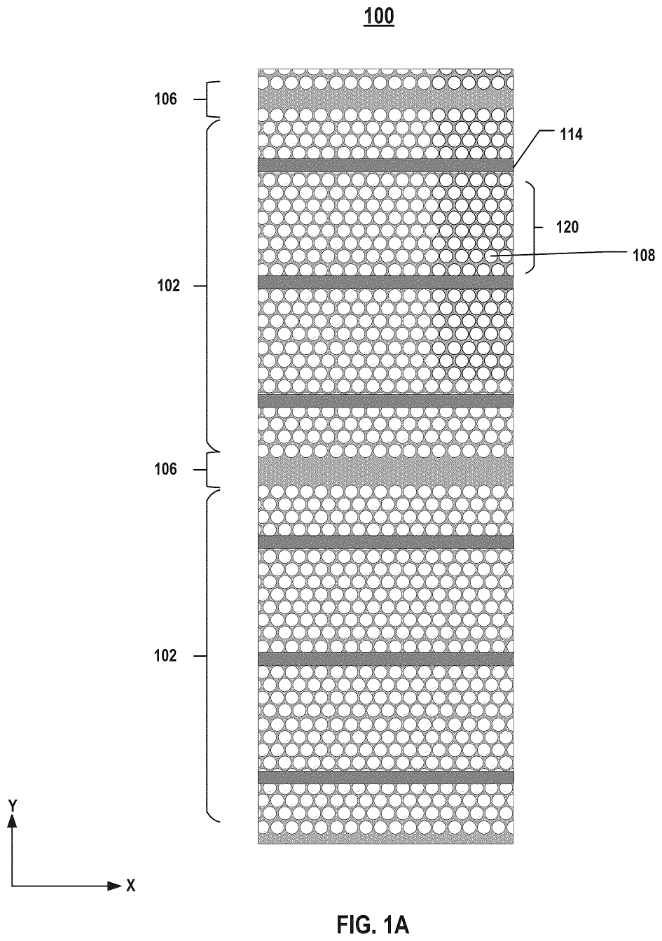

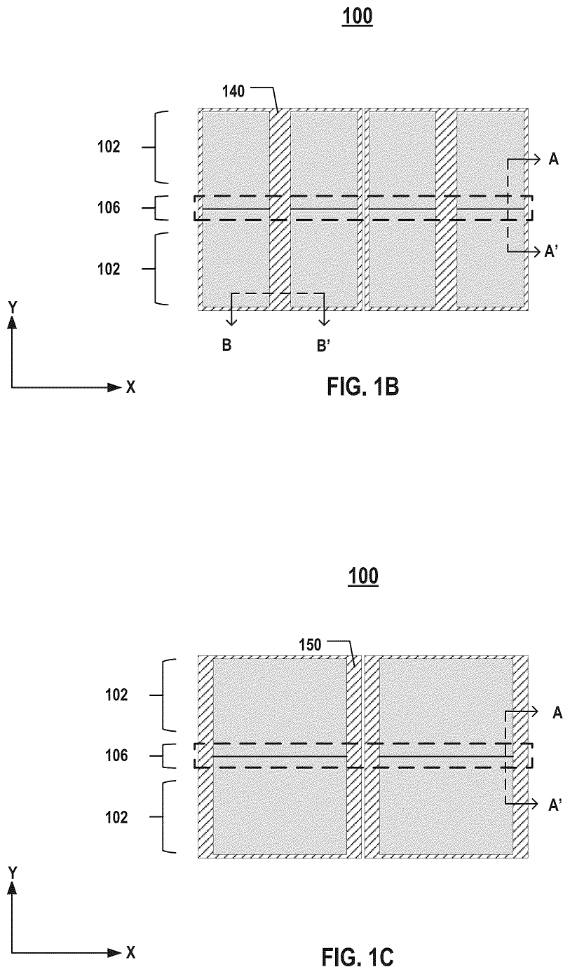

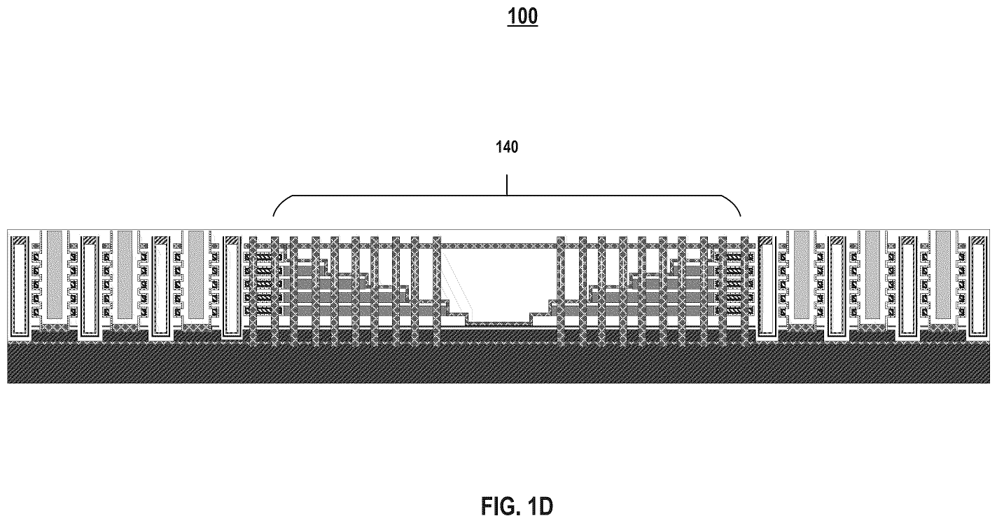

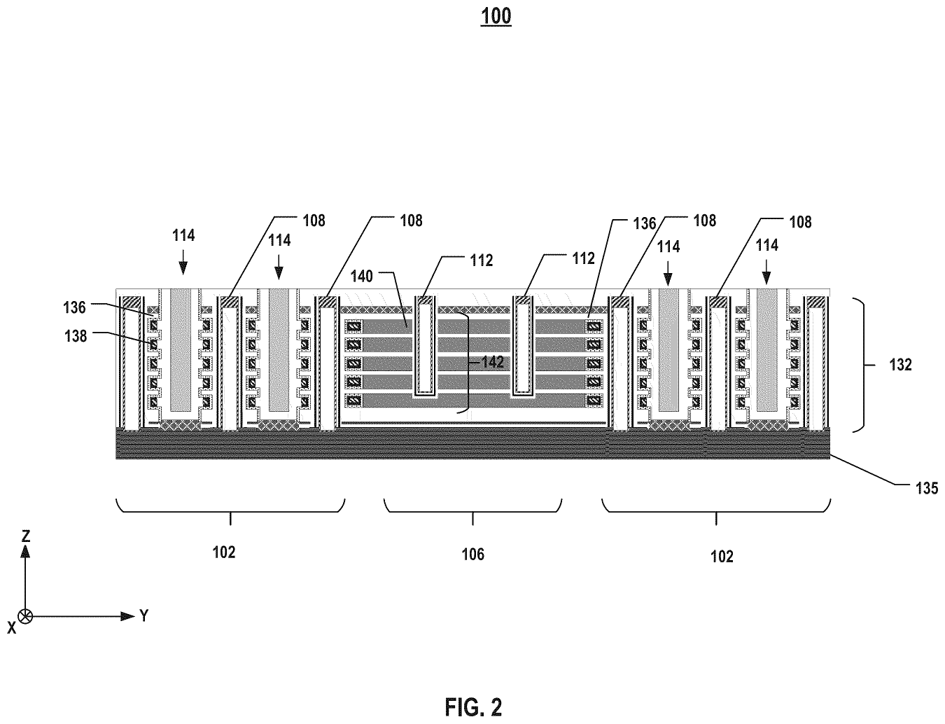

FIGS. 1A-1C illustrate plan views of exemplary 3D memory device 100, according to some aspects of the present disclosure. FIG. 2 illustrates a cross-section of 3D memory device 100 along line AA′ at a stage of a manufacturing process, according to some aspects of the present disclosure. For the purpose of better describing the present disclosure, the plan view of 3D memory device 100 in FIGS. 1A-1C and the cross-section of 3D memory device 100 in FIG. 2 will be discussed together.

3D memory device 100 may include a plurality of memory planes 102, each memory plane 102 may include a plurality of memory blocks 120, and a separation block 106 extending laterally to separate memory planes 102. Memory block 120 may include a memory stack 132 formed on the substrate 134, and an array of channel structures 108 each extending vertically through memory stack 132. In some implementations, substrate 134 may include silicon (e.g., single crystalline silicon), silicon germanium (SiGe), gallium arsenide (GaAs), germanium (Ge), silicon on insulator (SOI), germanium on insulator (GOI), or any other suitable materials. In some implementations, substrate 134 may be a thinned substrate (e.g., a semiconductor layer), which was thinned by grinding, wet/dry etching, chemical mechanical polishing (CMP), or any combination thereof. In some implementations, substrate 134 may be formed by removing a carrier substrate and depositing a semiconductor layer under memory stack 132 and channel structures 108. In some implementations, the deposited semiconductor layer may be a polysilicon layer.

Memory stack 132 may include vertically interleaved conductive layers 138 (functioning as gate electrodes/word lines) and dielectric layers 136 (gate-to-gate dielectrics). 3D memory device 100 may also include multiple slit structures 114 (function as source contacts as array common source (ACS)) each extending vertically through memory stack 132 as well. In some implementations, conductive layers 138 may form the word lines and may include conductive materials including, but not limited to, tungsten (W), cobalt (Co), copper (Cu), aluminum (Al), polysilicon, doped silicon, silicides, or any combination thereof. In some implementations, dielectric layers 136 may include dielectric materials including, but not limited to, silicon oxide, silicon nitride, silicon oxynitride, or any combination thereof.

As shown in the plan view of FIG. 1A, memory planes 102 are arranged along the y-direction (e.g., the bit line direction) in the plan view. Each memory planes 102 may include a plurality of memory blocks 120 arranged along the y-direction and the plurality of slit structures 114 each between adjacent memory blocks 120 in the y-direction in the plan view. It is noted that x and y axes are included in FIG. 1A to illustrate two orthogonal directions in the wafer plane. The x-direction is the word line direction, and the y-direction is the bit line direction.

Slit structures 114 may extend vertically along the z-direction through memory stacks 132 and may also extend laterally along the x-direction to separate memory stacks 132 into multiple blocks 120. In some implementations, slit structures 114 may include a slit contact, formed by filling a slit opening with conductive materials including but not limited to, W, Co, Cu, Al, polysilicon, silicides, or any combination thereof. Slit structures 114 may further include a composite spacer disposed laterally between the slit contact and memory stacks 132 to electrically insulate the slit contact from surrounding conductive layers 138 (the gate conductors in memory stacks 132).

As shown in the cross-section of FIG. 2, memory plane 102 may further include channel structures 108 each extending vertically through memory stack 132. In some implementations, channel structures 108 may include a semiconductor channel, and a memory film formed between the semiconductor channel and memory stack 132. The memory film may be a multilayer structure to achieve the storage function in 3D memory device 100. The memory film may include a composite layer of silicon oxide/silicon oxynitride/silicon oxide (ONO). The ONO structure may be formed over the semiconductor channel, and the ONO structure (the memory film) is also located between the semiconductor channel and conductive layers 138, such as word lines. In some implementations, the semiconductor channel may include silicon, such as amorphous silicon, polysilicon, or single crystalline silicon. The word lines may serve as a control gate and is electrically or electronically coupled to the memory film in response to a bias.

As shown in FIG. 1A, separation block 106 extends laterally in the x-direction (e.g., the word line direction) between adjacent memory planes 102 arranged in the y-direction (e.g., the bit line direction). Separation block 106 may electrically separate memory planes 102. FIGS. 1B and 1C illustrate two different implementations of the current disclosure. In FIG. 1B, a staircase area 140 locates at the center area of memory planes 102, and in FIG. 1C, a staircase area 150 locates at the edge of memory planes 102. FIG. 1D illustrates a cross-sections of exemplary 3D memory device 100 along the line BB′ in FIG. 1B, according to some aspects of the present disclosure.

As shown in FIG. 2, which is a cross-section of 3D memory device 100, separation block 106 may include a dielectric stack 142. Dielectric stack 142 includes vertically interleaved dielectric layers 140 and dielectric layers 136. Dielectric layers 136 may extend across memory planes 102 and separation block 106. Dielectric layers 140 may electrically separate conductive layers 138 of two adjacent memory planes 102. In some implementations, dielectric layers 136 may include dielectric materials including, but not limited to, silicon oxide, silicon nitride, silicon oxynitride, or any combination thereof. In some implementations, dielectric layers 140 may include dielectric materials including, but not limited to, silicon oxide, silicon nitride, silicon oxynitride, or any combination thereof.

In some implementations, separation block 106 may further include a plurality of dummy channel structures 112. Dummy channel structures 112 may extend vertically in dielectric stack 142. In some implementations, dummy channel structures 112 may extend vertically through partial of dielectric stack 142. In other words, dummy channel structures 112 may not penetrate the whole stack structure of dielectric stack 142 but only partial of dielectric stack 142. In some implementations, the length of dummy channel structures 112 is shorter than the length of channel structures 108. In some implementations, when dummy channel structures 112 and channel structures 108 are formed in round shape in the plan view of 3D memory device 100, the diameter of dummy channel structures 112 may be smaller than the diameter of channel structures 108, as shown in FIG. 1. It is understood that dummy channel structures 112 and channel structures 108 may be not in round shape in the plan view of 3D memory device 100, and the size of dummy channel structures 112 may be smaller than the size of channel structures 108.

In some implementations, dummy channel structures 112 may have structures similar to channel structures 108. In some implementations, dummy channel structures 112 may include the semiconductor channel, and the memory film formed between the semiconductor channel and dielectric stack 142. The memory film may include a composite layer of silicon oxide/silicon oxynitride/silicon oxide (ONO). In some implementations, dummy channel structures 112 may have structures different from channel structures 108.

In some implementations, as shown in FIG. 2, the substrate (e.g., having single crystalline silicon) is replaced with a semiconductor layer 135 in contact with the semiconductor channel of a bottom open channel structure on the source end of NAND memory string. Parts of the memory film of channel structures 108 on the source end can be removed to expose the semiconductor channel to contact semiconductor layer 135. In some implementations, part of the semiconductor channel on the source end of NAND memory string is doped to form a doped region that is in contact with semiconductor layer 135. Semiconductor layer 135 can include semiconductor materials, such as polysilicon. In some implementations, semiconductor layer 135 includes N-type doped polysilicon to enable GILD erase operations.

Since memory planes 102 are separated by separation block 106 in the y-direction, and separation block 106 is formed by dielectric stack 142, memory planes 102 can be electrically isolated by separation block 106 in the y-direction. Hence, the gate line slit structures are not needed in separation block 106 because adjacent memory planes 102 can be electrically isolated by dielectric stack 142, and the area between two adjacent memory planes 102 can be reduced. Furthermore, in the implementation that have dummy channel structures 112, since dummy channel structures 112 have a smaller diameter or size (as known as the critical dimension (CD)) than channel structures 108, the uniformity of channel etching may be further improved and provide better support in separation block 106.

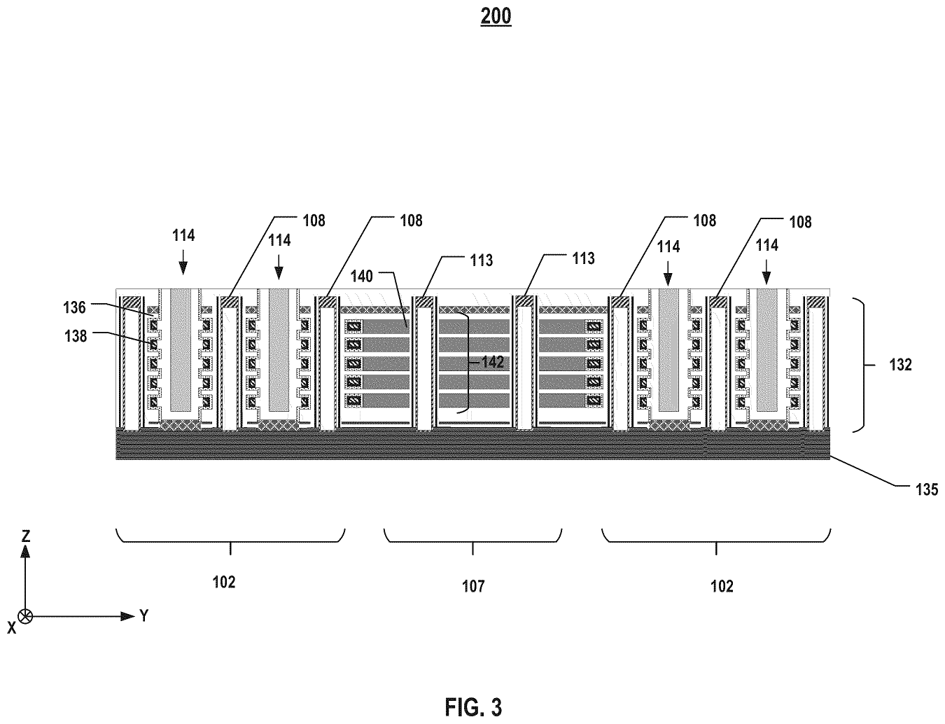

FIG. 3 illustrates another cross-section of a 3D memory device 200, according to some aspects of the present disclosure. As shown in FIG. 3, memory planes 102 are separated by a separation block 107 in the y-direction. Separation block 107 extends laterally in the x-direction (e.g., the word line direction) between adjacent memory planes 102 arranged in the y-direction (e.g., the bit line direction). Separation block 107 may electrically separate memory planes 102. As shown in FIG. 3, separation block 107 may include dielectric stack 142. In some implementations, the structures and materials of dielectric stack 142 in separation block 107 may be similar to those of dielectric stack 142 in separation block 106.

In some implementations, separation block 107 may further include a plurality of dummy channel structures 113. Dummy channel structures 113 may extend vertically in dielectric stack 142. In some implementations, dummy channel structures 113 may extend vertically through dielectric stack 142. In some implementations, the length of dummy channel structures 113 may be similar or the same as the length of channel structures 108. In some implementations, dummy channel structures 113 may extend vertically through dielectric stack 142. In other words, dummy channel structures 113 may penetrate the whole stack structure of dielectric stack 142. In some implementations, when dummy channel structures 113 and channel structures 108 are formed in round shape in the plan view of 3D memory device 200, the diameter of dummy channel structures 113 may be the same as the diameter of channel structures 108. It is understood that dummy channel structures 113 and channel structures 108 may be not in round shape in the plan view of 3D memory device 200, and the size of dummy channel structures 113 may be smaller than the size of channel structures 108.

Since memory planes 102 are separated by separation block 107 in the y-direction, and separation block 107 is formed by dielectric stack 142, memory planes 102 can be electrically isolated by separation block 107 in the y-direction. Hence, the gate line slit structures are not needed in separation block 107 because adjacent memory planes 102 can be electrically isolated by dielectric stack 142, and the area of between two adjacent memory planes 102 can be reduced.

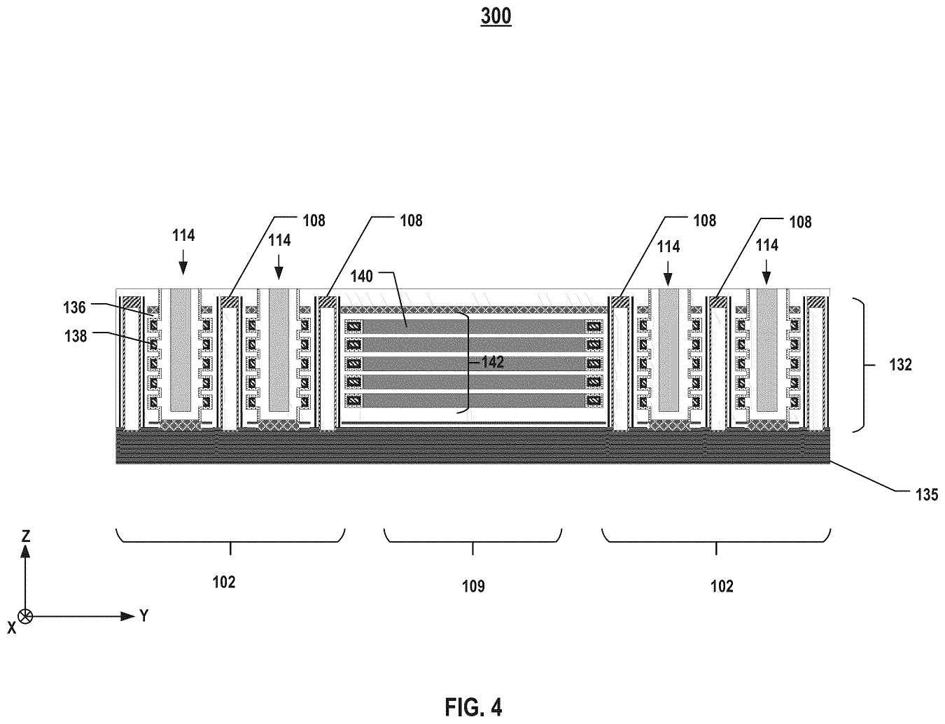

FIG. 4 illustrates a cross-section of a 3D memory device 300, according to some aspects of the present disclosure. As shown in FIG. 4, memory planes 102 are separated by a separation block 109 in the y-direction. Separation block 109 extends laterally in the x-direction (e.g., the word line direction) between adjacent memory planes 102 arranged in the y-direction (e.g., the bit line direction). Separation block 109 may electrically separate memory planes 102. As shown in FIG. 4, separation block 109 may include dielectric stack 142. In some implementations, the structures and materials of dielectric stack 142 in separation block 109 may be similar to those of dielectric stack 142 in separation block 106.

In some implementations, separation block 109 may not have any dummy channel structures formed within. In other words, separation block 109 may include dielectric stack 142 only. Since memory planes 102 are separated by separation block 109 in the y-direction, and separation block 109 is formed by dielectric stack 142, memory planes 102 can be electrically isolated by separation block 109 in the y-direction. Hence, the gate line slit structures are not needed in separation block 109, and the area between two adjacent memory planes 102 can be reduced.

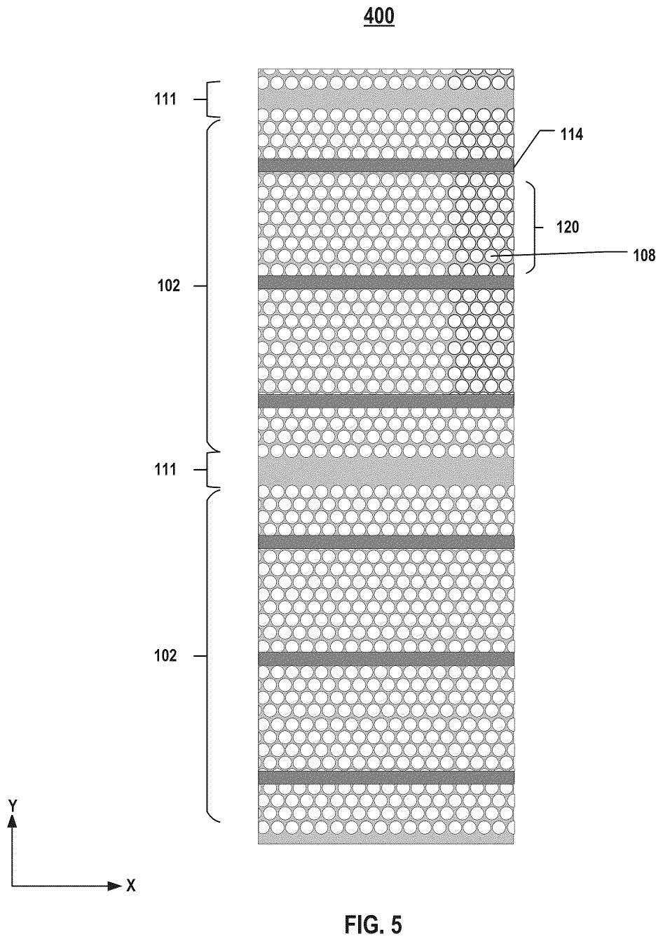

FIG. 5 illustrates a plan view of 3D memory device 400, according to some aspects of the present disclosure. As shown in FIG. 5, memory planes 102 are separated by a separation block 111 in the y-direction, and separation block 111 includes dielectric stack 142 only. In other words, there is no dummy channel structure or gate line slit structure formed in separation block 111.

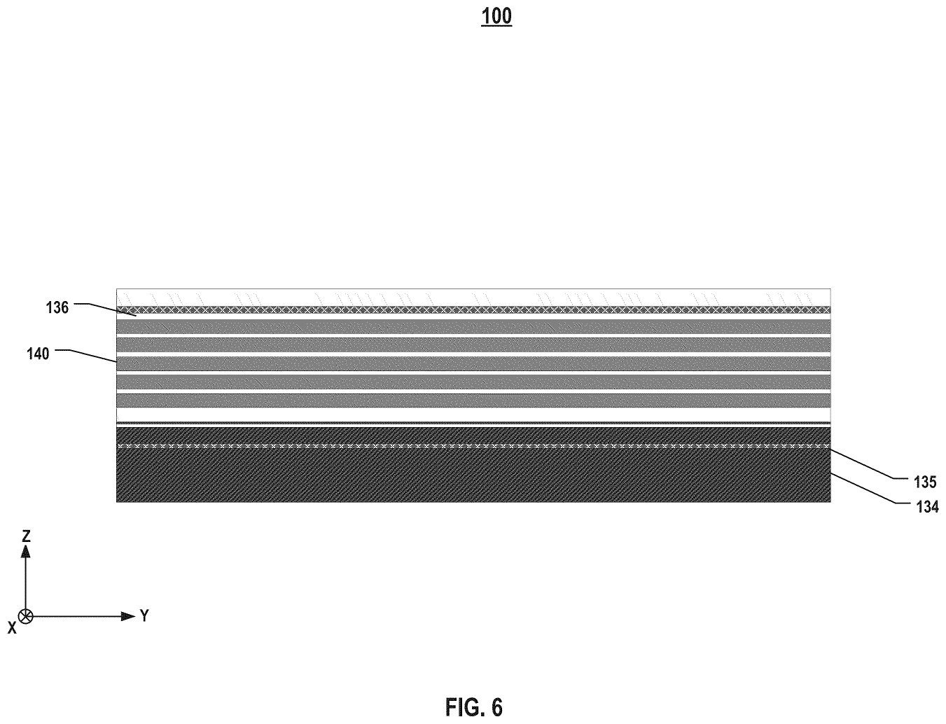

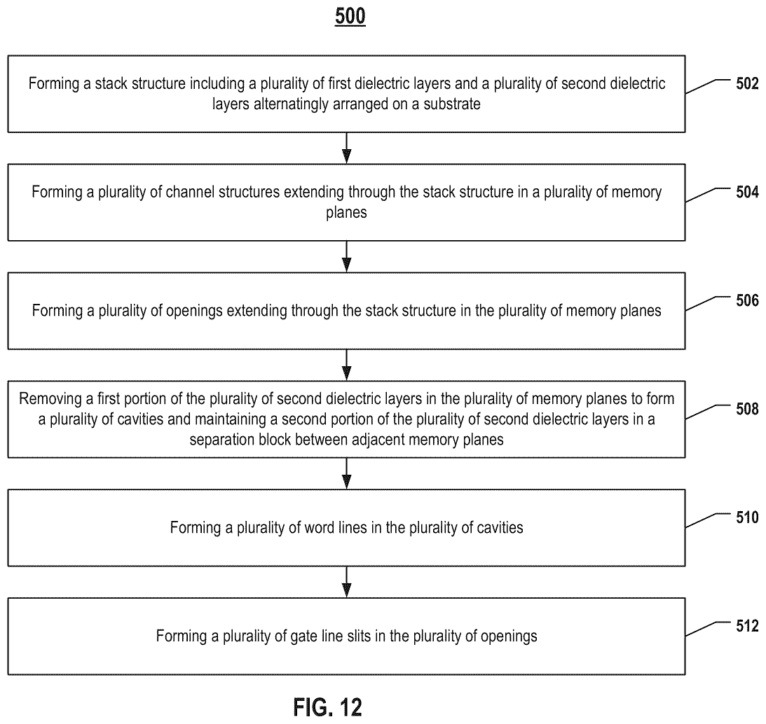

FIGS. 6-11 illustrate cross-sections of 3D memory device 100 at different stages of a manufacturing process, according to some aspects of the present disclosure. FIG. 12 illustrates a flowchart of an exemplary method 500 for forming 3D memory device 100, according to some aspects of the present disclosure. For the purpose of better describing the present disclosure, the cross-sections of 3D memory device 100 in FIGS. 6-11 and method 500 in FIG. 12 will be discussed together. It is understood that the operations shown in method 500 are not exhaustive and that other operations may be performed as well before, after, or between any of the illustrated operations. Further, some of the operations may be performed simultaneously, or in a different order than shown in FIGS. 6-11 and FIG. 12.

As shown in FIG. 6 and operation 502 in FIG. 12, a stack structure including the plurality of dielectric layers 136 and the plurality of dielectric layers 140 is formed on substrate 134. Dielectric layers 136 and dielectric layers 140 are alternatingly arranged on substrate 134. Dielectric layers 136 and dielectric layers 140 may extend along the x-direction and the y-direction. In some implementations, each dielectric layer 136 may include a layer of silicon oxide, and each dielectric layer 140 may include a layer of silicon nitride. Dielectric layers 136 and dielectric layers 140 may be formed by one or more thin film deposition processes including, but not limited to, chemical vapor deposition (CVD), physical vapor deposition (PVD), atomic layer deposition (ALD), or any combination thereof. In some implementations, a pad oxide layer 135 may be formed between the substrate and the stack structure by depositing dielectric materials, such as silicon oxide, on the substrate.

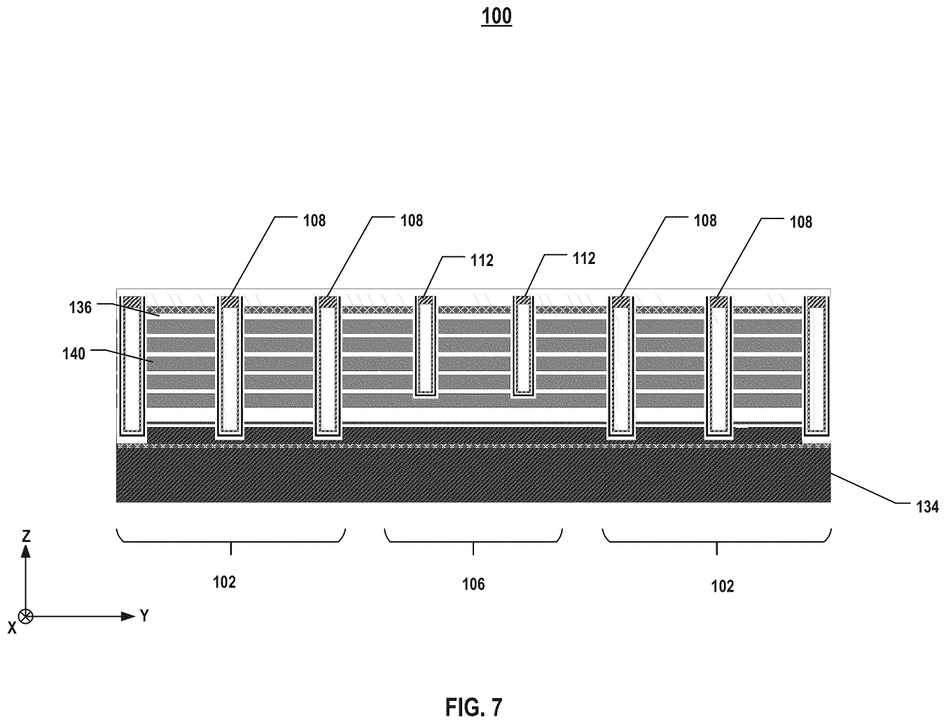

As shown in FIG. 7 and operation 504 in FIG. 12, channel structures 108, and dummy channel structures 112 are formed in the stack structure along the z-direction. In some implementations, channel structures 108, and dummy channel structures 112 may have the same structure. In some implementations, dummy channel structures 112 may have a structure different from channel structures 108.

In some implementations, each channel structures 108 may include a semiconductor channel and a memory film formed over the semiconductor channel. In some implementations, a channel hole is formed in the stack structure along the z-direction. In some implementations, an etch process may be performed to form the channel hole in the stack structure that extends vertically (z-direction) through the interleaved dielectric layers 136 and dielectric layers 140. In some implementations, fabrication processes for forming the channel hole may include wet etching and/or dry etching, such as deep reactive ion etching (DRIE). In some implementations, the channel hole may extend further into substrate 134. Then, a blocking layer, a storage layer, a tunneling layer, and a semiconductor channel may be sequentially formed in the channel hole.

In some implementations, each dummy channel structure 112 may also include the semiconductor channel and the memory film formed over the semiconductor channel. In some implementations, a channel hole of dummy channel structure 112 is formed in the stack structure along the z-direction. In some implementations, the channel hole of dummy channel structure 112 may be smaller than the channel hole of channel structures 108 and channel structures 110. In some implementations, when dummy channel structures 112 and channel structures 108 are formed in round shape in the plan view, the channel hole of dummy channel structure 112 may have a diameter smaller than the diameter of the channel hole of channel structures 108. It is understood that dummy channel structures 112 and channel structures 108 may be not in round shape in the plan view, and the size of dummy channel structures 112 may be smaller than the size of channel structures 108. In some implementations, in the cross-section, the channel hole of dummy channel structure 112 may have a length shorter than the length of the channel hole of channel structures 108.

In some implementations, the etch process may be performed to form the channel hole of dummy channel structure 112 in the stack structure that extends vertically (z-direction) through the interleaved dielectric layers 136 and dielectric layers 140. In some implementations, fabrication processes for forming the channel hole of dummy channel structure 112 may be the same as forming the channel hole of channel structures 108. Then, a blocking layer, a storage layer, a tunneling layer, and a semiconductor channel may be sequentially formed in the channel hole to form dummy channel structure 112.

Because dummy channel structures 112 have a smaller size (as known as the critical dimension (CD)) than channel structures 108, the uniformity of channel etching may be further improved.

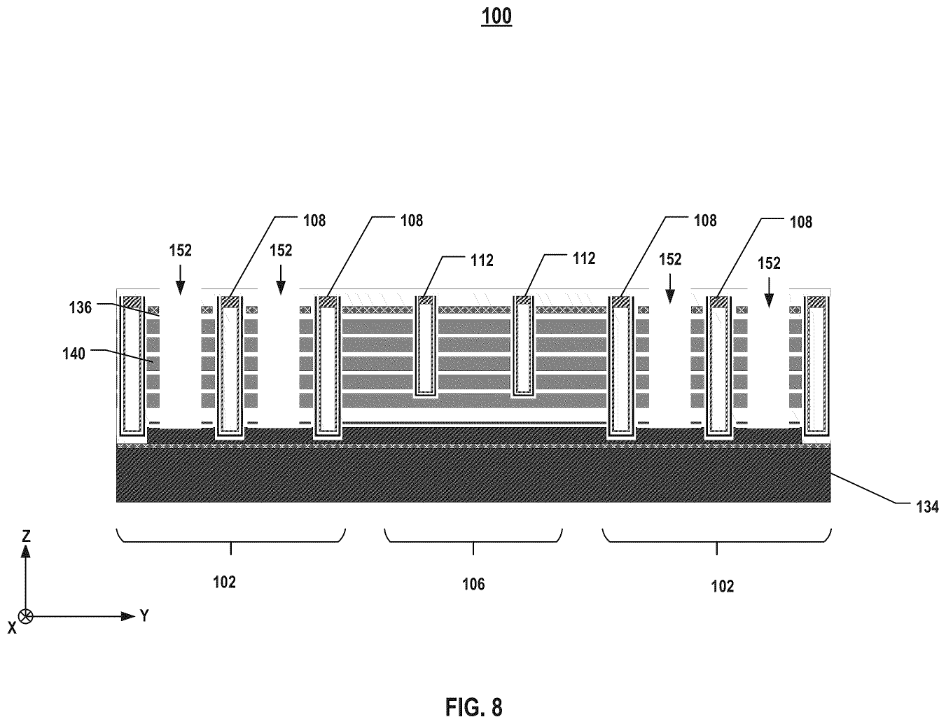

As shown in FIG. 8 and operation 506 in FIG. 12, a plurality of openings 152 are formed extending vertically through the stack structure in memory planes 102 of the stack structure. It is understood that, in FIG. 8, one channel structure 108 is disposed between openings 152 in memory planes 102for illustration purposes only, and more channel structures 108 may be formed between openings 152 in some implementations. In some implementations, multiple channel structures 108 or multiple rows of channel structures 108 may be formed between openings 152 in memory planes 102. In some implementations, openings 152 may be formed in memory planes 102 only. In other words, there is no opening 152 formed in separation block 106. In some implementations, openings 152 may be formed by dry etching, wet etching, or other suitable processes.

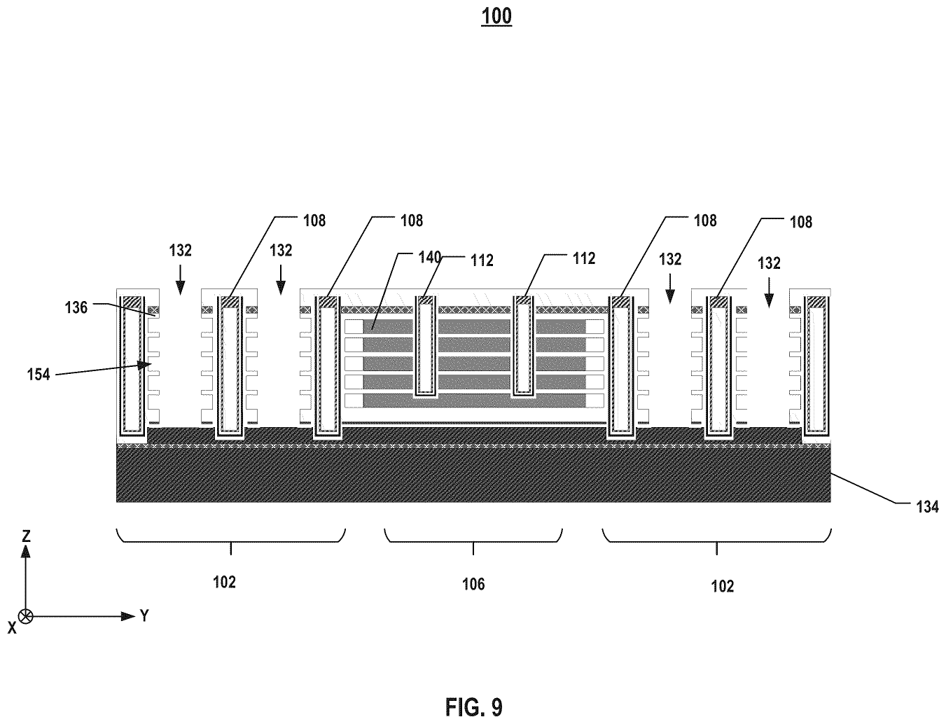

As shown in FIG. 9 and operation 508 in FIG. 12, a portion of dielectric layers 140 in memory planes 102 of the stack structure is removed. In some implementations, the portion of dielectric layers 140 in memory planes 102 may be removed by wet etching to form lateral recesses 154. Another portion of dielectric layers 140 in separation block 106 may remain.

In some implementations, the portion of dielectric layers 140 in memory planes 102 may be wet etched by applying a wet etchant through openings 152, creating lateral recesses 154 interleaved between dielectric layers 136. The wet etchant can include phosphoric acid for etching dielectric layers 140 including silicon nitride. In some implementations, the etching rate and/or etching time are controlled to remove only the parts of dielectric layers 140 in memory planes 102, leaving remainders of dielectric layers 140 in separation block 106.

As shown in FIG. 9, the wet etchant can be applied from openings 152 to remove parts of dielectric layers 140 within each memory plane 102. By controlling the etching time, the wet etchant does not remove parts of dielectric layers 140 in separation block 106. In some implementations, the length of lateral recesses 154 may be about half of the length of memory block 120 along the y-direction.

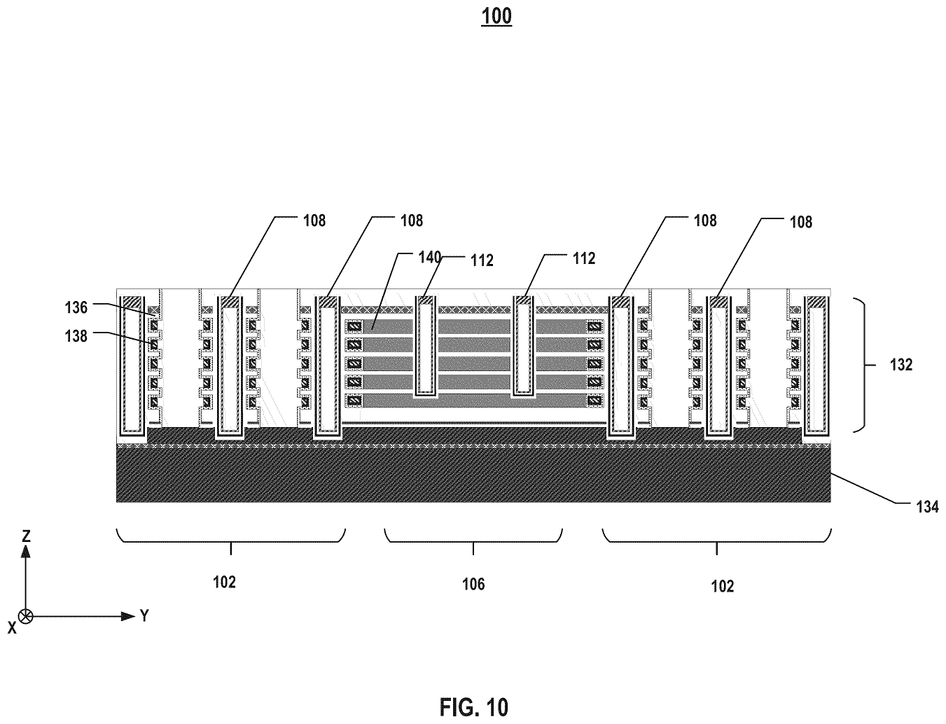

As shown in FIG. 10 and operation 510 in FIG. 12, a plurality of word lines may be formed in the plurality of lateral recesses 154. In some implementations, conductive layers 138 (including gate electrodes and adhesive layers) are deposited into lateral recesses 154 through openings 152. In some implementations, a gate dielectric layer is deposited into lateral recesses 154 prior to conductive layers 138, such that conductive layers 138 are deposited on the gate dielectric layer. Conductive layers 138, such as metal layers, can be deposited using one or more thin film deposition processes, such as ALD, CVD, PVD, any other suitable processes, or any combination thereof. In some implementations, conductive layers 138 fully fill lateral recesses 154 and thus, are in contact with the remainders of dielectric layers 140, respectively, after depositing conductive layers 138. As a result, part of the dielectric stack is thereby replaced with memory stack 132 in memory planes 102 including vertically interleaved conductive layers 138 and dielectric layers 136.

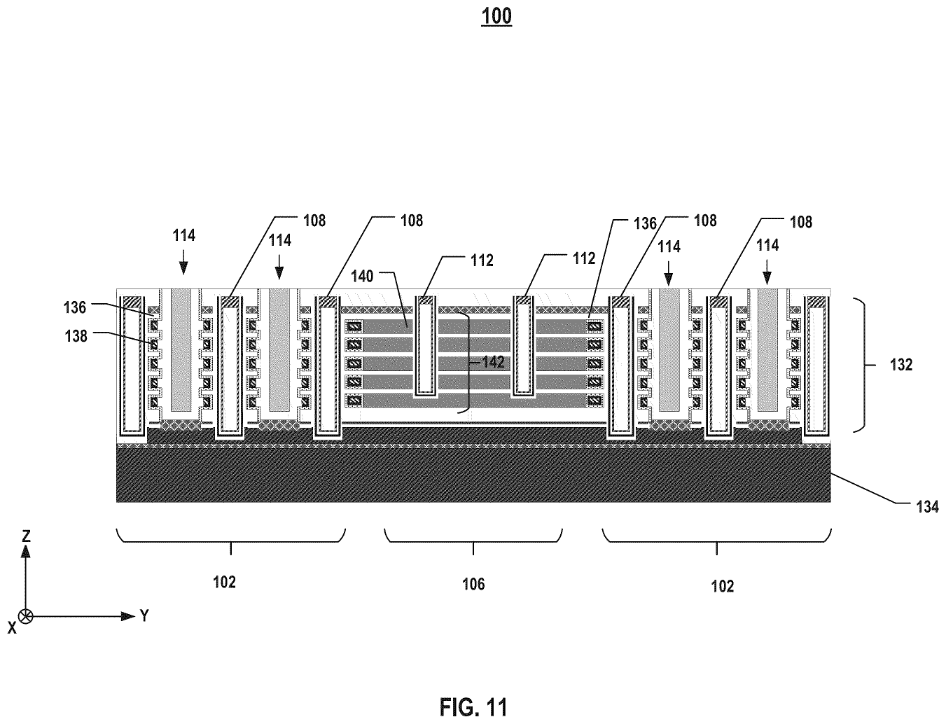

As shown in FIG. 11 and operation 512 in FIG. 12, the plurality of gate line slits (slit structures 114) are formed in the plurality of openings 152. Slit structures 114 may extend vertically through memory stack 132 in memory planes 102. Slit structures 114 may be formed by depositing dielectrics into opening 152 using one or more thin film deposition processes, such as ALD, CVD, PVD, any other suitable processes, or any combination thereof. It is understood that, in some implementations, slit structures 114 may be formed by depositing dielectrics (as a spacer) and conductive materials (as a contact) into opening 152.

Since memory planes 102 are separated by separation block 106 in the y-direction, and separation block 106 is formed by dielectric stack 142, adjacent memory planes 102 can be electrically isolated by separation block 106 in the y-direction. Hence, the gate line slit structures are not needed in separation block 106, and the area between adjacent memory planes 102 can be reduced.

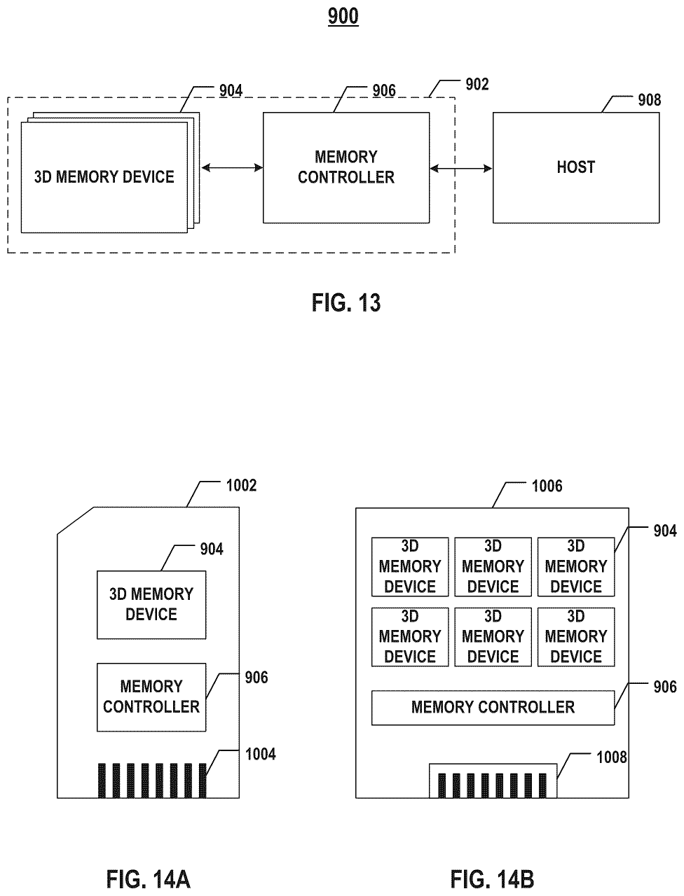

FIG. 13 illustrates a block diagram of an exemplary system 900 having a memory device, according to some aspects of the present disclosure. System 900 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 13, system 900 can include a host 908 and a memory system 902 having one or more memory devices 904 and a memory controller 906. Host 908 can be a processor of an electronic device, such as a central processing unit (CPU), or a system-on-chip (SoC), such as an application processor (AP). Host 908 can be configured to send or receive data to or from memory devices 904.

Memory device 904 can be any memory device disclosed in the present disclosure. As disclosed above in detail, memory device 904, such as a NAND Flash memory device, may have a controlled and predefined discharge current in the discharge operation of discharging the bit lines. Memory controller 906 is coupled to memory device 904 and host 908 and is configured to control memory device 904, according to some implementations. Memory controller 906 can manage the data stored in memory device 904 and communicate with host 908. For example, memory controller 906 may be coupled to memory device 904, such as 3D memory device 100 described above, and memory controller 906 may be configured to control the operations of channel structures 108 and/or 110 through the peripheral device. By forming the structure according to the present disclosure, the area of 3D memory device 100 may be reduced by using the separation block disclosed.

In some implementations, memory controller 906 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 906 is designed for operating in a high duty-cycle environment SSDs or embedded multi-media-cards (eMMCs) used as data storage for mobile devices, such as smartphones, tablets, laptop computers, etc., and enterprise storage arrays. Memory controller 906 can be configured to control operations of memory device 904, such as read, erase, and program operations. Memory controller 906 can also be configured to manage various functions with respect to the data stored or to be stored in memory device 904 including, but not limited to bad-block management, garbage collection, logical-to-physical address conversion, wear leveling, etc. In some implementations, memory controller 906 is further configured to process error correction codes (ECCs) with respect to the data read from or written to memory device 904. Any other suitable functions may be performed by memory controller 906 as well, for example, formatting memory device 904. Memory controller 906 can communicate with an external device (e.g., host 908) according to a particular communication protocol. For example, memory controller 906 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 906 and one or more memory devices 904 can be integrated into various types of storage devices, for example, be included in the same package, such as a universal Flash storage (UFS) package or an eMMC package. That is, memory system 902 can be implemented and packaged into different types of end electronic products. In one example as shown in FIG. 14A, memory controller 906 and a single memory device 904 may be integrated into a memory card 1002. Memory card 1002 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1002 can further include a memory card connector 1004 coupling memory card 1002 with a host (e.g., host 908 in FIG. 13). In another example as shown in FIG. 14B, memory controller 906 and multiple memory devices 904 may be integrated into an SSD 1006. SSD 1006 can further include an SSD connector 1008 coupling SSD 1006 with a host (e.g., host 908 in FIG. 13). In some implementations, the storage capacity and/or the operation speed of SSD 1006 is greater than those of memory card 1002.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A three-dimensional (3D) memory device, comprising:
a plurality of memory planes, each memory plane comprising a plurality of memory blocks, each memory block comprising:
a memory stack comprising interleaved conductive layers and first dielectric layers; and
a plurality of channel structures each extending through the memory stack; and
a separation block extending laterally to separate each two adjacent memory planes, each separation block comprising:
a dielectric stack comprising interleaved second dielectric layers and the first dielectric layers,
wherein the first dielectric layers extend across the memory blocks and the separation block, and the second dielectric layers separate the conductive layers of two adjacent memory blocks.

2. The 3D memory device of claim 1, wherein each separation block further comprises:
a plurality of dummy channel structures extending in the dielectric stack.

3. The 3D memory device of claim 2, wherein the dummy channel structures extend through partial of the dielectric stack.

4. The 3D memory device of claim 1, wherein a diameter of the channel structures is larger than a diameter of the dummy channel structures.

5. The 3D memory device of claim 1, wherein each memory block further comprises at least one slit structure extending through the memory stack.

6. The 3D memory device of claim 5, wherein at least one channel structure is disposed between the slit structure and the separation block.

7. A three-dimensional (3D) memory device, comprising:
a plurality of memory blocks, each memory block comprising:
a memory stack comprising interleaved conductive layers and first dielectric layers;
a plurality of channel structures each extending through the memory stack; and
a slit structure extending through the memory stack; and
a separation block extending laterally to separate two adjacent memory blocks, the separation block comprising:
a dielectric stack comprising interleaved second dielectric layers and the first dielectric layers.

8. The 3D memory device of claim 7, wherein the slit structure is disposed only in the plurality of memory blocks.

9. The 3D memory device of claim 7, wherein the first dielectric layers extend across the memory blocks and the separation block, and the second dielectric layers separate the conductive layers in two adjacent memory blocks.

10. The 3D memory device of claim 7, wherein the separation block further comprises:
a plurality of dummy channel structures each extending in the dielectric stack.

11. The 3D memory device of claim 7, wherein the dummy channel structures extend through partial of the dielectric stack.

12. The 3D memory device of claim 10, wherein a diameter of the channel structures is larger than a diameter of the dummy channel structures.

13. The 3D memory device of claim 10, wherein at least one channel structure is disposed between the slit structure and the separation block.

14. The 3D memory device of claim 10, wherein at least one channel structure is disposed between the slit structure and the dummy channel structures.

15. A method for forming a three-dimensional (3D) memory device, comprising:
forming a stack structure comprising a plurality of first dielectric layers and a plurality of second dielectric layers alternatingly arranged on a substrate;
forming a plurality of channel structures extending through the stack structure in a plurality of memory planes;
forming a plurality of openings extending through the stack structure in the plurality of memory planes;
removing a first portion of the plurality of second dielectric layers in the plurality of memory planes to form a plurality of cavities and maintaining a second portion of the plurality of second dielectric layers in a separation block between adjacent memory planes;
forming a plurality of word lines in the plurality of cavities; and
forming a plurality of slit structures in the plurality of openings.

16. The method of claim 15, wherein removing the first portion of the plurality of second dielectric layers in the plurality of memory planes to form the plurality of cavities, further comprises:
removing the first portion of the plurality of second dielectric layers in the plurality of memory planes through the plurality of openings.

17. The method of claim 15, wherein forming the plurality of channel structures extending through the stack structure in the plurality of memory planes, further comprises:
forming a plurality of channel openings extending through the stack structure in the plurality of memory planes; and
forming the plurality of channel structures in the plurality of channel openings.

18. The method of claim 17, further comprising:
forming a plurality of dummy channel openings extending through the stack structure in the separation block between adjacent memory planes; and
forming a plurality of dummy channel structures in the plurality of dummy channel openings.

19. The method of claim 18, wherein a first length of the plurality of channel structures is larger than a second length of the plurality of dummy channel structures.

20. The method of claim 18, wherein a size of the plurality of channel structures is larger than a size of the plurality of dummy channel structures.
